(19) United States
(12) Patent Application Publication
(10) Pub. No.: US 2019/0326401 A1
(43) Pub. Date: Oct. 24, 2019

(54) BODY CONNECTION FOR A SILICON-ON-INSULATOR DEVICE

(71) Applicant: QUALCOMM Incorporated, San Diego, CA (US)

(72) Inventors: Plamen Vassilev KOLEV, San Diego, CA (US); Sinan GOKTEPELI, San Diego, CA (US); Peter Graeme CLARKE, San Diego, CA (US)

(21) Appl. No.: 15/958,792

(22) Filed: Apr. 20, 2018

(51) Int. Cl. H01L 29/10; H01L 29/78; H01L 29/66

(52) U.S. Cl. CPC H01L 29/1087; H01L 29/66477; H01L 29/7841

(57) ABSTRACT

In certain aspects, a silicon-on-insulator device comprises a back insulating layer and a semiconductor layer on the back insulating layer. The semiconductor layer includes a source region of a first conductive type having a front source surface and a back source surface, a channel region of a second conductive type have a front channel surface and a back channel surface, and a drain region of the first conductive type. The silicon-on-insulator device further comprises a gate insulating layer on the front channel surface of the channel region and a back silicidation layer on at least a portion of the back source surface and a portion of back channel surface.

### BACKGROUND

### Field

Aspects of the present disclosure relate to silicon-on-insulator devices, and more particularly, to structures and methods for connecting body of a silicon-on-insulator MOSFET.

### Background

Silicon-on-insulator (SOI) technology refers to the use of a layered silicon-insulator-silicon substrate in place of a conventional silicon substrate in semiconductor manufacturing, especially microelectronics, to reduce parasitic device capacitance, thereby improving performance. An integrated circuit built using SOI devices may show processing speed that is 30% faster than a comparable bulk-based integrated circuit and power consumption being reduced by as much as 80%, which makes it ideal for mobile devices. SOI chips also reduce the soft error rate, which is data corruption caused by cosmic rays and natural radioactive background signals. SOI transistors offer a unique opportunity for CMOS architectures to be more scalable. The buried oxide layer limits the punch-through that may exist on deep sub-micron bulk devices.

Due to the existence of the buried oxide layer, the body of an SOI MOSFET is often floating in circuit design, meaning no connection of the body to a bias voltage. Floating body of an SOI MOSFET results in an effect called floating body effect, a dependency of the body potential on the history of the SOI MOSFET's biasing and the carrier recombination processes. For many applications, leaving body floating causes undesired effects such as kinks in the output characteristics, leading to non-linearity, reduced breakdown voltage, and degraded reliability. For such application, body connection may be needed. However, conventional body connection approaches often comes at a cost of reduced device performance and/or increased device size. Accordingly, it would be beneficial to provide a body connection scheme without substantial performance or area penalty.

### SUMMARY

The following presents a simplified summary of one or more implementations to provide a basic understanding of such implementations. This summary is not an extensive overview of all contemplated implementations, and is intended to neither identify key nor critical elements of all implementations nor delineate the scope of any or all implementations. The sole purpose of the summary is to present concepts relate to one or more implementations in a simplified form as a prelude to a more detailed description that is presented later.

In one aspect, a silicon-on-insulator device comprises a back insulating layer and a semiconductor layer on the back insulating layer. The semiconductor layer includes a source region of a first conductive type having a front source surface and a back source surface, a channel region of a second conductive type having a front channel surface and a back channel surface, and a drain region of the first conductive type. The silicon-on-insulator device further comprises a gate insulating layer on the front channel surface of the channel region and a back silicidation layer on at least a portion of the back source surface and a portion of back channel surface.

In another aspect, a method comprises providing a silicon-on-insulator wafer having front metal connection system, a MOSFET, a back oxide layer, and a sacrificial substrate. The MOSFET includes a source region having a front source surface and a back source surface, a drain region, and a channel region having a front channel surface and a back channel surface. The method further comprises bonding the silicon-on-insulator wafer to a handle wafer, removing the sacrificial substrate, patterning and etching the back insulating layer to expose a portion of the back source surface and the back channel surface of the MOSFET, and forming a back silicidation layer on the source region and the channel region through the exposed back source surface and back channel surface.

To accomplish the foregoing and related ends, one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the described implementations are intended to include all such aspects and their equivalents.

### BRIEF DESCRIPTION OF THE DRAWINGS

FIG. 1a illustrates an example body connection for an SOI MOSFET according to certain aspects of the present disclosure.

FIG. 1b illustrates another example body connection for an SOI MOSFET according to certain aspects of the present disclosure.

FIG. 2 illustrates an example circuitry according to certain aspects of the present disclosure.

FIG. 3 illustrates an exemplary SOI MOSFET with body connection according to certain aspects of the present disclosure.

FIGS. 4a-4e illustrate an exemplary process flow in making a body connection for an SOI MOSFET according to certain aspects of the present disclosure.

FIG. 5 illustrates an exemplary method in making a body connection for an SOI MOSFET according to certain aspects of the present disclosure.

### DETAILED DESCRIPTION

The detailed description set forth below, in connection with the appended drawings, is intended as a description of various aspects and is not intended to represent the only aspects in which the concepts described herein may be practiced. The detailed description includes specific details for the purpose of providing an understanding of the various concepts. However, it will be apparent to those skilled in the art that these concepts may be practiced without these specific details. In some instances, well-known structures and components are shown in block diagram form in order to avoid obscuring such concepts.

Semiconductor-on-insulator (SOI) devices are widely used for their excellent electrical properties including lower threshold voltage, smaller parasitic capacitance, less current leakage and good switching property, etc. Conventionally, the silicon film in the channel region (body) is electrically floating. Leaving the body floating complicates device behavior due to floating body effect, such as parasitic bipolar effect, kink effect, history-dependent characteristics, etc. The floating body effect causes use of SOI devices in certain applications, such as RF, mixed signal, or high speed circuit design, challenging. The traditional remedy to the floating body effect is to provide body connection. However, the efficiency of the conventional body connection is limited and such connection often degrades device performance and consumes significant device area.

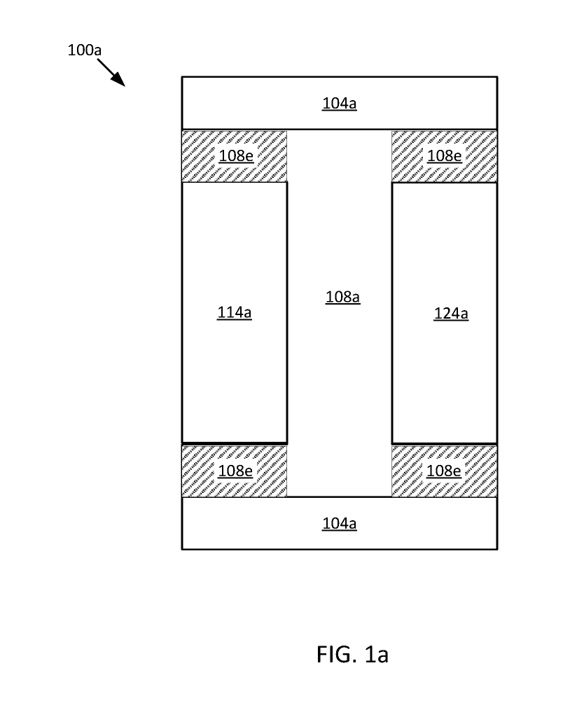

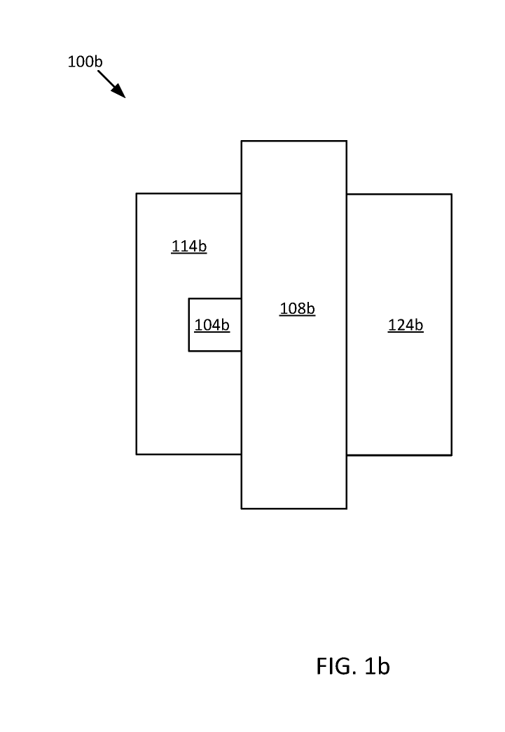

FIG. 1a illustrates an example body connection for an SOI MOSFET according to certain aspects of the present disclosure. From top-down view, the SOI MOSFET 100a comprises an H-shape gate having main gate 108a and gate extensions 108e, a source 114a, a drain 124a, and a body connection 104a in one or both sides of main gate 108a. As illustrated in FIG. 1a, to accommodate the body connection 104a, the main gate 108a is extended through the gate extensions 108e. Such extensions increase device size and add extra parasitic gate capacitance.

FIG. 1b illustrates another example body connection for an SOI MOSFET according to certain aspects of the present disclosure. From top-down view, the SOI MOSFET 100b comprises a gate 108b, a source 114b, a drain 124b, and a body connection 104b inside the source 114b. Such placement of body connection increases the size of the source thus increase the device size. It also reduces source to channel edge and increases source resistance. As a result, the device performance is degraded. Therefore, it would be beneficial to provide a body connections scheme that minimizes area and performance impact.

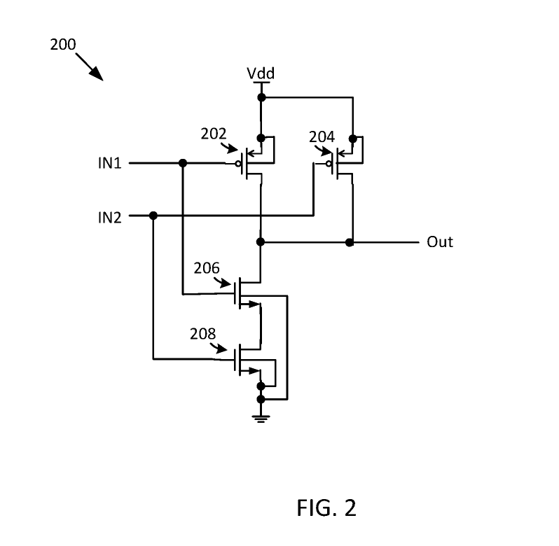

In many circuit designs, the body of an NMOS transistor is connected to a ground while the body of a PMOS transistor is connected to a supply voltage. For an NMOS transistor whose source is connected to the ground or a PMOS transistor whose source is connected to the supply voltage, the body and the source of the transistor are electrically coupled. FIG. 2 illustrates such an example. The circuit 200 is a two-input NAND gate with two inputs IN1 and IN2 and an output OUT. Both sources and both bodies of the PMOS transistors 202 and 204 are electrically coupled and connected to a supply voltage Vdd. While the source of NMOS transistor 206 is not electrically coupled to the body of the NMOS transistor 206, the source and the body of the NMOS transistor 208 are electrically coupled and connected to a ground. In an SOI circuit where the body connection is needed, for a transistor whose body and source are electrically coupled, certain body connection arrangement may be made to minimize the effect on device size or performance.

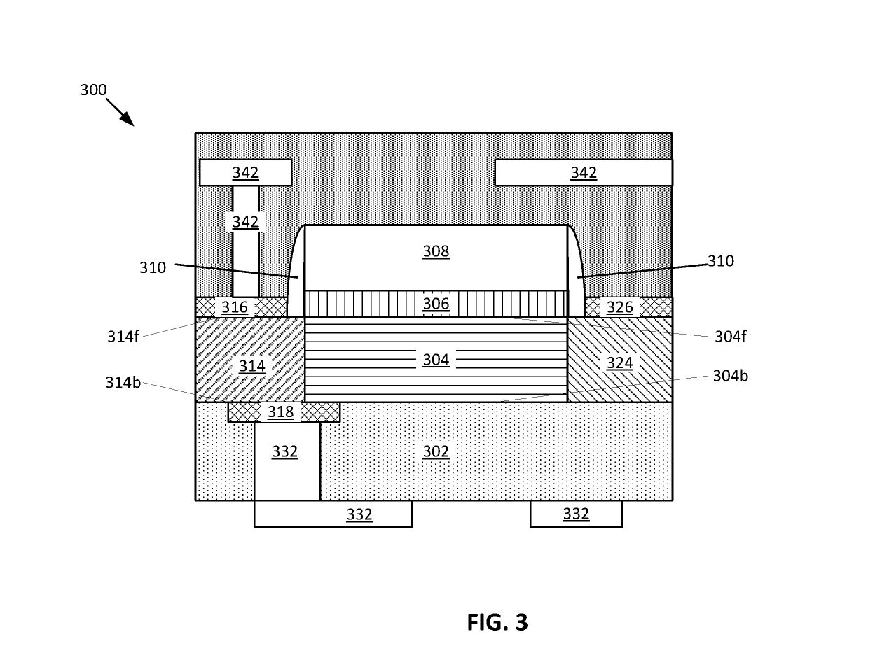

FIG. 3 illustrates an exemplary SOI MOSFET with body connection according to certain aspects of the present disclosure. The MOSFET 300 comprises a back insulating layer 302 and a semiconductor layer on the back insulating layer 302. The semiconductor layer includes a source region 314, a channel region 304, and a drain region 324. The conductive type of the source region 314 and the drain region 324 are opposite to the conductive type of the channel region 304. The source region 314 and the drain region 324 may be of a first conductive type and the channel region 304 may be of a second conductive type. For example, for an N-MOSFET, the source region 314 and the drain region 324 are N-type while the channel region 304 is P-type. For a P-MOSFET, the source region 314 and the drain region 324 are P-type while the channel region 304 is N-type. The source region 314 has a front source surface 314f and a back source surface 314b. The back source surface 314b is opposite to the front source surface 314f. The back source surface 314b is closer to the back insulating layer 302 than the front source surface 314f. Similarly, the channel region 304 has a front channel surface 304f and a back channel surface 304b. The back channel surface 304b is opposite to the front channel surface 304f. The back source channel 314b is closer to the back insulating layer 302 than the front channel surface 304f. A gate insulating layer 306 is on the front channel surface 304f of the channel region 304. A gate conducting layer 308 is on the gate insulating layer 306.

The MOSFET 300 further comprises a back silicidation layer 318 on at least a portion of the back source surface 314b of the source region 314 and a portion of back channel surface 304b of the channel region 304. The back silicidation layer 318 electrically couples the channel region 304 to the source region 314. Thus, through source region 314, the channel region 304 may be connected to a supply voltage for a PMOS transistor or a ground for an NMOS transistor. A separate body connection or body contact is not needed.

The back silicidation layer 318 is formed through a silicidation process, an anneal process resulting in the formation of metal-silicon alloy (silicide) to act as a contact or contact interface for low contact resistance. For example, Titanium may be deposited on silicon to form TiSi₂ as a result of silicidation. Other suitable materials are possible, such as CoSi₂, NiSi, etc.

The MOSFET 300 may further comprise a front silicidation layer 316 on the front source surface 314f and a front silicidation layer 326 on the drain region 324. The front silicidation layer 316 provides an interface for connection of the source region 314, and thus the channel region 304, to a front metal connection system 342. The front metal connection system 342 may include contacts, vias, and multi-level metal layers. The front metal connection system 342 may connect the source region 314 to a supply voltage for a PMOS transistor or a ground for an NMOS transistor. The front metal connection system 342 may connect the source region 314 to other signals.

The MOSFET 300 may also comprise a back metal connection system 332. The back metal connection system 332 may include contacts to the back silicidation layer 318 and may also include vias and one or more other metal layers. The source region 314 and/or the channel region 304 may be connected to a supply voltage or a ground or a signal through the back metal connection system 332.

The MOSFET 300 may further comprise a spacer 310. The spacer 310 electrically isolates the source region 314 and the front silicidation layer 316 from the gate conducting layer 308.

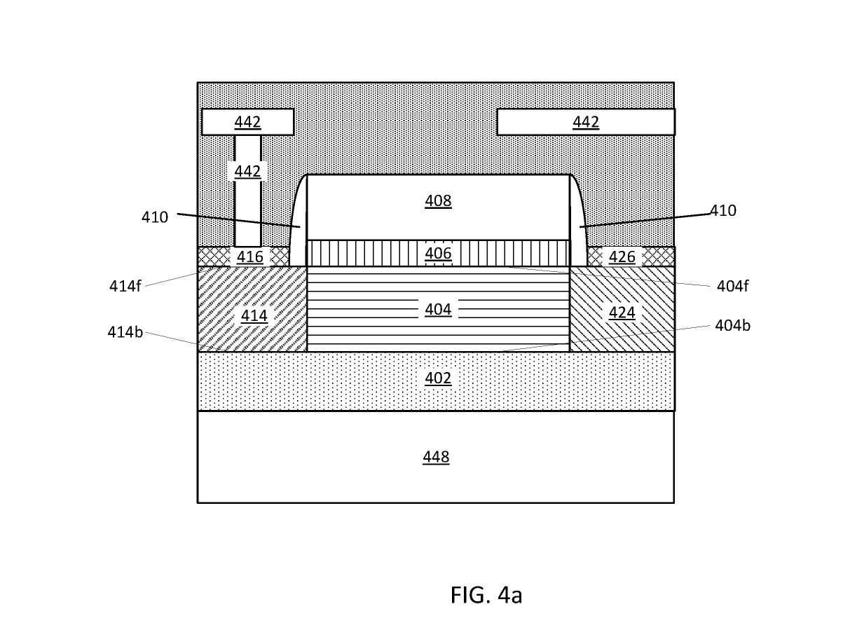

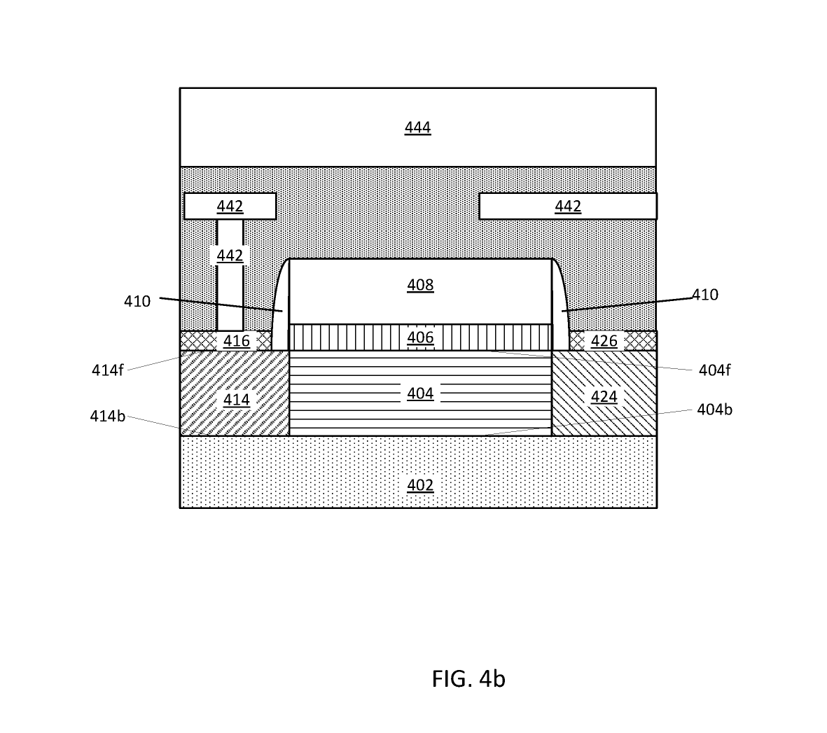

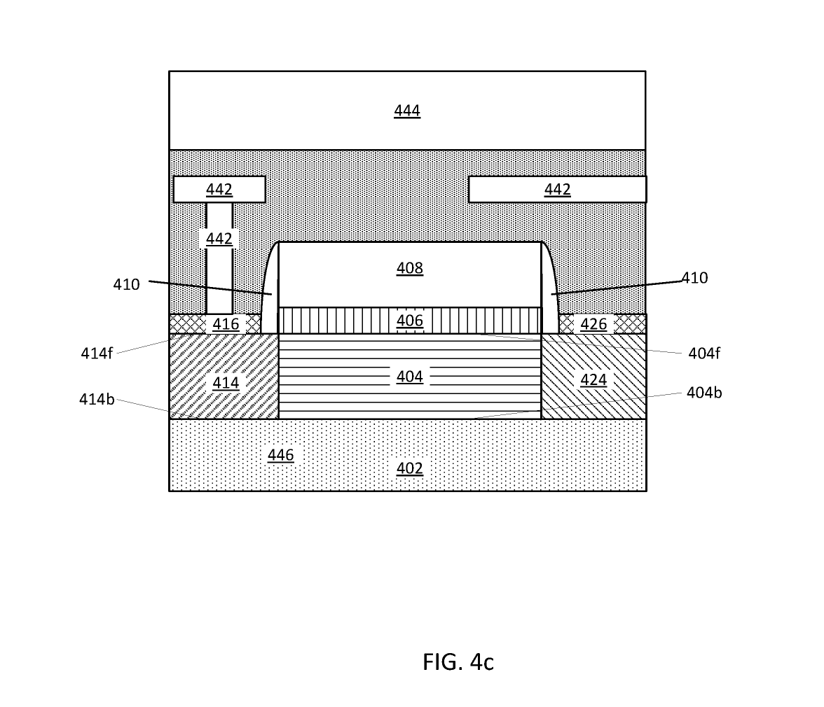

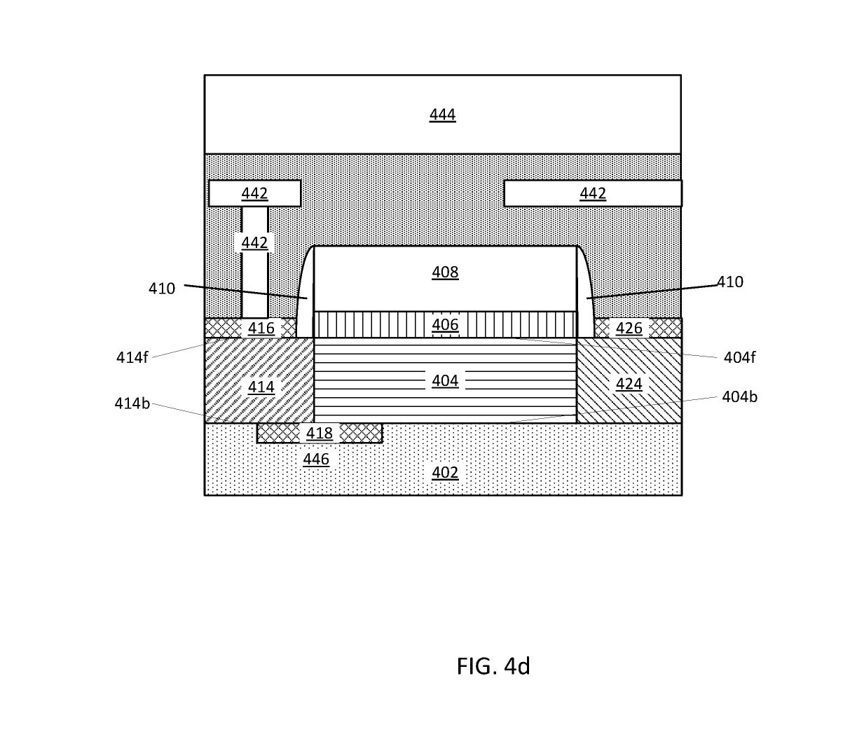

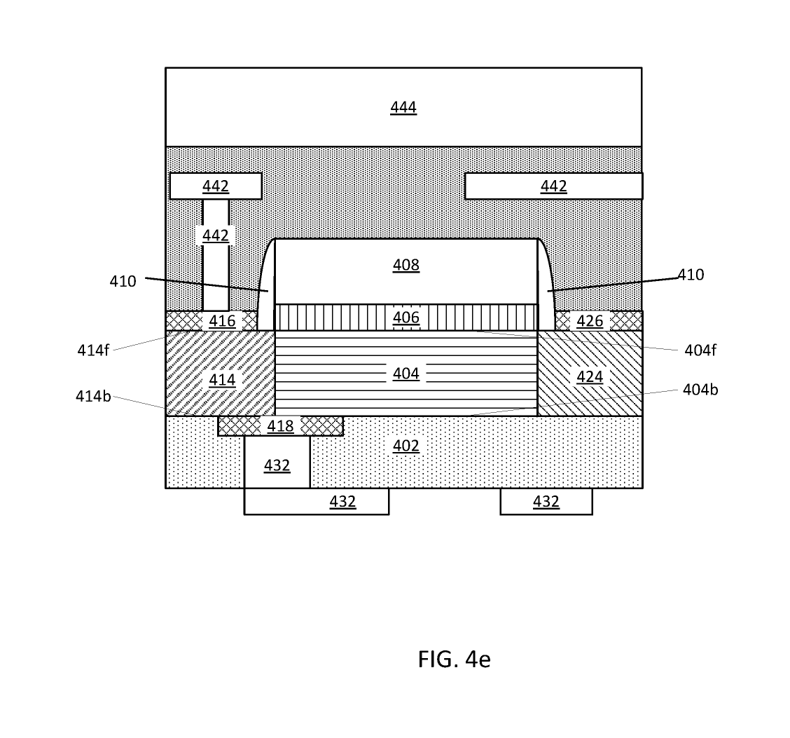

FIGS. 4a-4e illustrate an exemplary process flow in making a body connection for an SOI MOSFET according to certain aspects of the present disclosure. In FIG. 4a, an SOI wafer with MOSFETs is provided. The SOI wafer comprises a sacrificial substrate 448, a back insulating layer 402, at least a MOSFET, and a front metal connection system 442. The MOSFET comprises a source region 414, a channel region 404, and a drain region 424, all on the back insulating layer 402. In addition, the MOSFET may comprise a front silicidation layer 416 on the source region 414 and a front silicidation layer 426 on the drain region 424. The source region 414 has a front source surface 414f and a back source surface 414b. The channel region 404 has a front channel surface 404f and a back channel surface 404b. The MOSFET also comprises a gate insulating layer 406 on the channel region 404, a gate conducting layer 408 on the gate insulating layer 406, and a spacer 410 at the sides of the gate conducting layer 408. Further, the front metal connection system 442 provides supply voltage, ground, and/or signal connection for the MOSFET.

In FIG. 4b, the SOI wafer is bonded to a handle wafer 444. After the bonding of the handle wafer 444, the sacrificial substrate 448 is removed, exposing the back insulating layer 402.

In FIG. 4c, the back insulating layer 402 is patterned and etched with an opening 446. The opening 446 exposes a portion or all of the back source surface 414b and a portion or all of the back channel surface 404b.

In FIG. 4d, a back silicidation layer 418 is formed over the exposed portion of the back source surface 414b and the exposed portion of the back channel surface 404b. The back silicidation layer 418 electrically couples the channel region 404 to the source region 414. Thus, through source region 414, the channel region 404 may be connected to a supply voltage for a PMOS transistor or a ground for an NMOS transistor.

In FIG. 4e, a back metal connection system 432 may be formed. The back metal connection system 432 may include contacts to the back silicidation layer 418, vias, and one or more other metal layers. The source region 414 and/or the channel region 404 may be connected to a supply voltage, a ground, or a signal through the back metal connection system 432.

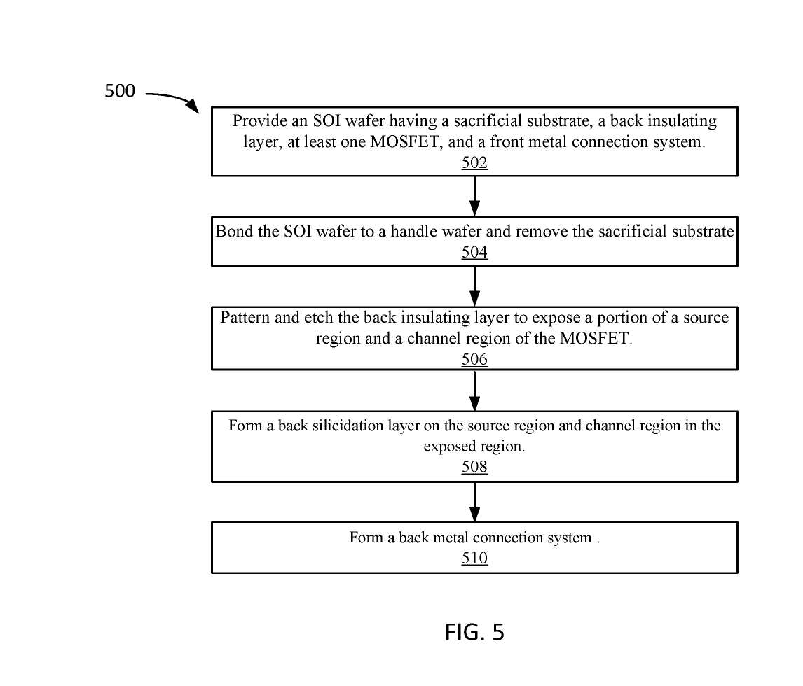

FIG. 5 illustrates an exemplary method 500 in making a body connection for an SOI MOSFET according to certain aspects of the present disclosure. At 502, an SOI wafer with MOSFETs is provided. The SOI wafer comprises a sacrificial substrate (e.g., the sacrificial substrate 448), a back insulating layer (e.g., the back insulating layer 302 or 402), at least a MOSFET, and a front metal connection system (e.g., the front metal connection system 342 or 442). The MOSFET comprises a source region (e.g., the source region 314 or 414), a channel region (e.g., the channel region 304 or 404), and a drain region (e.g., the drain region 324 or 424), all on the back insulating layer. In addition, the MOSFET may comprise a front silicidation layer (e.g., the front silicidation layer 316 or 416) on the source region and a front silicidation layer (e.g., the front silicidation layer 326 or 426) on the drain region. The MOSFET also comprises a gate insulating layer (e.g., the gate insulating layer 306 or 406) on the channel region, a gate conducting layer (e.g., the gate conducting layer 308 or 408) on the gate insulating layer, and a spacer (e.g., the spacer 310 or 410) at the sides of the gate conducting layer. Further, The front metal connection system provides supply voltage, ground, and/or signal connection for the MOSFET.

At 504, the SOI wafer is bonded to a handle wafer (e.g., the handle wafer 444). After the bonding of the handle wafer, the sacrificial substrate is removed, exposing the back insulating layer.

At 506, the back insulating layer is patterned and etched with an opening (e.g., the opening 446). The opening exposes a portion or all of the back source surface and a portion or all of the back channel surface.

At 508, a back silicidation layer (e.g., the back silicidation layer 318 or 418) is formed in the exposed back source surface and the exposed back channel surface. The back silicidation layer electrically couples the channel region to the source region. Thus, through source region, the channel region may be connected to a supply voltage for a PMOS transistor or a ground for an NMOS transistor.

At 510, a back metal connection system (e.g., the back metal connection system 332 or 432) may be formed. The back metal connection system may include contacts to the back silicidation layer, vias, and one or more metal layers. The source region and/or the channel region may be connected to a supply voltage or a ground or a signal through the back metal connection system.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A silicon-on-insulator device, comprising:
a back insulating layer;
a semiconductor layer on the back insulating layer, wherein the semiconductor layer includes a source region of a first conductive type having a front source surface and a back source surface, a channel region of a second conductive type having a front channel surface and a back channel surface, and a drain region of the first conductive type;
a gate insulating layer on the front channel surface of the channel region;
a gate conducting layer on the gate insulating layer; and
a back silicidation layer on at least a portion of the back source surface and at least a portion of the back channel surface.

2. The silicon-on-insulator device of claim 1, wherein the back silicidation layer is configured to electrically couple the channel region to the source region.

3. The silicon-on-insulator device of claim 2, wherein the channel region is electrically coupled to a supply voltage or a ground through the source region.

4. The silicon-on-insulator device of claim 1, wherein the first conductive type is opposite to the second conductive type.

5. The silicon-on-insulator device of claim 4, wherein the first conductive type is N-type.

6. The silicon-on-insulator device of claim 4, wherein the first conductive type is P-type.

7. The silicon-on-insulator device of claim 1, further comprising a front silicidation layer on the front source surface.

8. The silicon-on-insulator device of claim 7, wherein the front silicidation layer is isolated from the gate conducting layer by a spacer.

9. The silicon-on-insulator device of claim 1, further comprising a back metal connection system coupled to the back silicidation layer.

10. The silicon-on-insulator device of claim 9, wherein the back metal connection system provides connection of a supply voltage or a ground or a signal to the source region and the channel region.

11. A method, comprising:
providing a silicon-on-insulator wafer having a front metal connection system, a MOSFET, a back insulating layer, and a sacrificial substrate, wherein the MOSFET has a source region having a front source surface and a back source surface, a drain region, and a channel region having a front channel surface and a back channel surface;
bonding the silicon-on-insulator wafer to a handle wafer;
removing the sacrificial substrate;
patterning and etching the back insulating layer to expose at least a portion of the back source surface and the back channel surface of the MOSFET; and
forming a back silicidation layer on the exposed back source region and the exposed back channel region.

12. The method of claim 11, wherein the back silicidation layer is configured to electrically couple the channel region to the source region.

13. The method of claim 12, wherein the channel region is electrically coupled to a supply voltage or a ground through the source region.

14. The method of claim 11, wherein the source region and the drain region is of a first conductive type and the channel region is of a second conductive type opposite to the first conductive type.

15. The method of claim 14, wherein the first conductive type is N-type.

16. The method of claim 14, wherein the first conductive type is P-type.

17. The method of claim 11, further comprising forming a front silicidation layer on the front source surface.

18. The method of claim 17, wherein the front silicidation layer is isolated from a gate conducting layer by a spacer.

19. The method of claim 11, further comprising forming a back metal connection system coupled to the back silicidation layer.

20. The method of claim 19, wherein the back metal connection system provides connection of a supply voltage or a ground or a signal to the source region and the channel region.
